(19) United States
(12) Patent Application Publication
(10) Pub. No.: US 2026/0282231 A1
(43) Pub. Date: Sep. 17, 2026

(54) CIRCUIT BOARD AND ELECTRONIC EQUIPMENT

(71) Applicant: CANON KABUSHIKI KAISHA, Tokyo (JP)

(72) Inventor: NOBUAKI YAMASHITA, Kanagawa (JP)

(21) Appl. No.: 19/558,534

(22) Filed: Mar. 6, 2026

(30) Foreign Application Priority Data
Mar. 11, 2025 (JP) 2025-038181

(51) Int. Cl. H05K 1/181

(52) U.S. Cl. CPC H05K 1/181; H05K 2201/10015; H05K 2201/10022; H05K 2201/1003

(57) ABSTRACT

The present disclosure discloses about a circuit board which includes: a printed wiring board; and a first chip component, a second chip component, and a third chip component which is placed on a first main surface of the printed wiring board. The first chip component has a first electrode and a second electrode. The second chip component has a third electrode and a fourth electrode. The third chip component has a fifth electrode and a sixth electrode. A distance between the first electrode and the first main surface is greater than a distance between the second electrode and the first main surface. A distance between the third electrode and the first main surface is greater than a distance between the fourth electrode and the first main surface.

### BACKGROUND

### Field of the Technology

The present disclosure relates to a circuit board on which a plurality of chip components are disposed, and electronic equipment.

### Description of the Related Art

In recent years, a risk of semiconductor apparatuses malfunctioning has increased with acceleration of circuit operation and reduction of power supply voltage. Under circumstances where reduction of component size and size reduction of circuit boards (in the present disclosure, also referred to as printed circuit boards) have also progressed, malfunctioning is also caused by noise interference between circuits, distortion of signal waveforms, etc. which occurs due to fluctuations in power supply potential which is generated during operation of the semiconductor apparatus. Malfunction of electronic equipment due to electromagnetic wave emission is also a problem. Accordingly, filter circuits which are formed by combining a plurality of chip components on a circuit board are widely applied as a measure to suppress noise.

Japanese Patent Laid-Open No. 2022-158047 discloses an electric circuit that includes an RC series circuit, a capacitor, and a noise filter, and that operates in a stable manner.

The method which is described in Japanese Patent Laid-Open No. 2022-158047 requires a large number of various components, which induces necessitating sufficient mounting area for these components.

A problem to be solved in the present disclosure is that an area which is occupied by a circuit which is formed by combining a plurality of chip components increases in size.

### SUMMARY

In order to solve the above problem, the present disclosure is a circuit board including: a printed wiring board; and a first chip component, a second chip component, and a third chip component which is placed on a first main surface of the printed wiring board. The first chip component has a first electrode and a second electrode. The second chip component has a third electrode and a fourth electrode. The third chip component has a fifth electrode and a sixth electrode. The first electrode, the third electrode, and the fifth electrode are connected to each other. The second electrode and the fourth electrode are connected to the printed wiring board. A distance between the first electrode and the first main surface is greater than a distance between the second electrode and the first main surface. A distance between the third electrode and the first main surface is greater than a distance between the fourth electrode and the first main surface.

In addition, the present disclosure is a circuit board including: a printed wiring board; and a first chip component, a second chip component, and a third chip component which is placed on a first main surface of the printed wiring board. The first chip component is a resistor component which includes a first electrode and a second electrode. The second chip component is a resistor component which includes a third electrode and a fourth electrode. The third chip component is a reactor component which includes a fifth electrode and a sixth electrode. The first electrode, the third electrode, and the fifth electrode are connected to each other, and the second electrode and the fourth electrode are connected to each other. The first chip component or the third chip component is disposed between the second chip component and the first main surface.

Features of the present disclosure will become apparent from the following description of embodiments with reference to the attached drawings. The following description of embodiments is described by way of example.

### BRIEF DESCRIPTION OF THE DRAWINGS

FIG. 1A is a front view of an image forming apparatus as an example of an electronic module according to a first embodiment.

FIG. 1B is a side view of the image forming apparatus as an example of the electronic module according to the first embodiment.

FIG. 2 is an explanatory diagram of a control module according to the first embodiment.

FIG. 3 is a perspective view of a circuit board according to the first embodiment.

FIG. 4A is an example of a front view of chip components according to a variation of the first embodiment.

FIG. 4B is another example of a front view of the chip components according to a variation of the first embodiment.

FIG. 4C is another example of a front view of the chip components according to a variation of the first embodiment.

FIG. 4D is another example of a front view of the chip components according to a variation of the first embodiment.

FIG. 5A is an example of a circuit which constitutes a filter and a result which is obtained by calculating a distribution of variation in resistance value, the circuit is formed by combining one resistor and one capacitor component.

FIG. 5B is another example of a circuit which constitutes a filter and a result which is obtained by calculating a distribution of variation in resistance value, the circuit is formed by combining one capacitor and two resistors which are connected in parallel.

FIG. 5C is another example of a circuit which constitutes a filter and a result which is obtained by calculating a distribution of variation in resistance value, the circuit is formed by combining one capacitor and three resistors which are connected in parallel.

FIG. 6A is a perspective view of a circuit board according to a second embodiment.

FIG. 6B is a front view of chip components according to the second embodiment.

FIG. 7 is a perspective view of a circuit board according to a third embodiment.

FIG. 8 is a perspective view of a circuit board according to a fourth embodiment.

FIG. 9A is a perspective view of a circuit board according to a fifth embodiment.

FIG. 9B is a perspective view of a circuit board according to a variation of the fifth embodiment.

FIG. 10 is a perspective view of a circuit board according to a sixth embodiment.

FIG. 11 is a perspective view of a circuit board according to a comparative example.

### DESCRIPTION OF THE EMBODIMENTS

Hereinafter, embodiments of the present disclosure will be described in detail with reference to the figures. However, the individual embodiments which are described below are each one embodiment of the present disclosure, and the present disclosure is not limited thereto. Components which are common in the figures will be described with reference to a plurality of figures, and description of the components which are denoted by common reference characters will be omitted as appropriate.

### First Embodiment

A first embodiment relates to a circuit board.

A circuit board of the present disclosure includes: a printed wiring board; and a first chip component, a second chip component, and a third chip component which is placed on a first main surface of the printed wiring board. The first chip component has a first electrode and a second electrode. The second chip component has a third electrode and a fourth electrode. The third chip component has a fifth electrode and a sixth electrode. The first electrode, the third electrode, and the fifth electrode are connected to each other. The second electrode and the fourth electrode are connected to the printed wiring board. A distance between the first electrode and the first main surface is greater than a distance between the second electrode and the first main surface. A distance between the third electrode and the first main surface is greater than a distance between the fourth electrode and the first main surface.

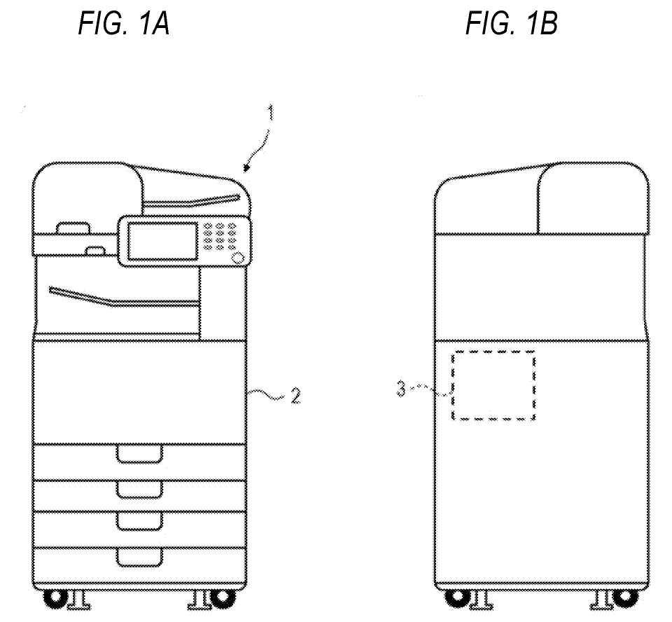

Electronic equipment of the present disclosure includes the circuit board of the present disclosure, an electrical apparatus, and a wiring component which is configured to connect the electrical apparatus and the circuit board of the present disclosure. FIG. 1A is a front view of an image forming apparatus as an example of the electronic equipment. FIG. 1B is a side view of the image forming apparatus. An image forming apparatus 1 is electrophotographic digital equipment such as a printer, a copier, a fax, or a multifunction machine, for example. The image forming apparatus 1 includes an apparatus main body 2 that forms an image on a sheet, a control module 3 that controls the apparatus main body 2, and a housing (not shown).

The control module 3 is disposed inside the housing of the apparatus main body 2. The apparatus main body 2 includes an image forming section that forms an image on a sheet and a conveying mechanism, which are not shown in FIGS. 1A and 1B. The image forming section includes a photosensitive drum, a charging unit, a developing unit, a transfer unit, a fixing unit, etc., which are not shown in FIGS. 1A and 1B.

The control module 3 is an electronic module as the circuit board of the present disclosure. The control module 3 receives image data from external equipment via an interface such as a local area network (LAN) or a universal serial bus (USB). The control module 3 performs processing on the received image data, transmits the image data to the apparatus main body 2, and controls the apparatus main body 2 so as to form an image on a sheet.

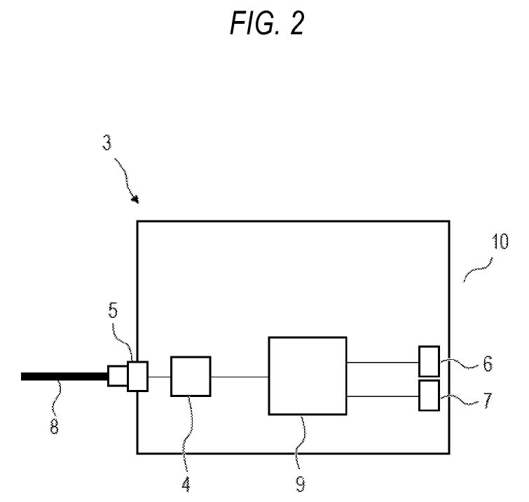

FIG. 2 is an explanatory diagram of the control module 3 according to the first embodiment. The control module 3 includes a semiconductor 9, which is an example of a first semiconductor. The control module 3 includes connectors 5, 6, and 7, a conversion chip 4, and a printed wiring board of the present disclosure (printed wiring board 10). The semiconductor 9, the connector 5, the connector 6, the connector 7, and the conversion chip 4 are disposed on the printed wiring board 10. The printed wiring board 10 is a rigid substrate.

A LAN cable 8 is connected to the connector 5, and the image data is received from the external equipment via the LAN cable 8. The conversion chip 4 processes the image data which are received at the connector 5, stores the image data in a memory controller and a memory device (not illustrated), reads the image data from the memory device, and outputs the image data to the semiconductor 9. The semiconductor 9 outputs the image data to the connectors 6 and 7, and transmits the image data to the image forming section which is connected to the connectors 6 and 7 by cables (not shown).

A circuit board of the present disclosure includes: a first chip component, a second chip component, and a third chip component, which are placed on a first main surface of the printed wiring board. In the circuit board of the present disclosure, the first chip component has a first electrode and a second electrode. The second chip component has a third electrode and a fourth electrode. The third chip component has a fifth electrode and a sixth electrode. The first electrode, the third electrode, and the fifth electrode are connected to each other. The second electrode and the fourth electrode are connected to the printed wiring board. A distance between the first electrode and the first main surface is greater than a distance between the second electrode and the first main surface. A distance between the third electrode and the first main surface is greater than a distance between the fourth electrode and the first main surface. In the circuit board of the present disclosure, a distance between the fifth electrode and the first main surface can be greater than a distance between the sixth electrode and the first main surface.

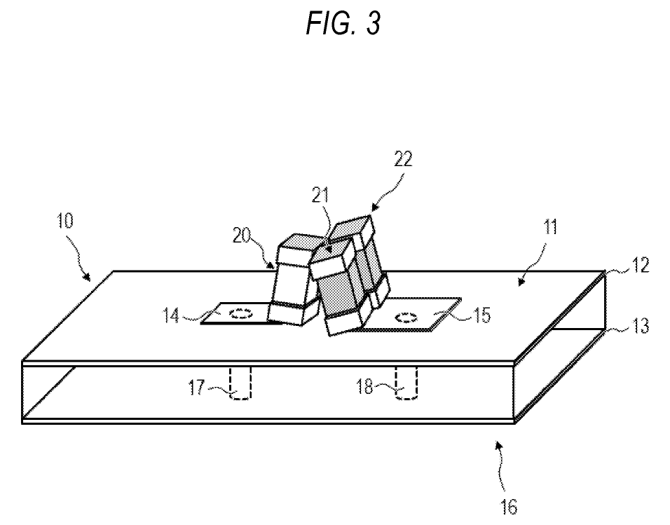

FIG. 3 is a perspective view which shows the printed wiring board 10 which constitutes the control module 3 according to the present embodiment. FIG. 3 illustrates a first main surface 11 of the printed wiring board 10. Three chip components (third chip component (chip component 20), first chip component (chip component 21), and second chip component (chip component 22)) are disposed on a first surface layer 12, which is the first main surface 11 of the printed wiring board 10. The three chip components (chip component 20, chip component 21, and chip component 22) are all disposed in upright on the printed wiring board 10.

The circuit board of the present disclosure can include a conductor member (wiring conductor 14 and wiring conductor 15) which is placed on the first main surface 11 of the printed wiring board 10, wherein the second electrode can be jointed to the conductor member with solder, and the fourth electrode can be jointed to the conductor member with solder.

In the circuit board of the present disclosure, the first electrode, the third electrode, and the fifth electrode can be connected to each other. One-side electrodes of the three chip components are electrically continuous with each other, and another-side electrodes are each electrically connected to the first surface layer 12 of the printed wiring board. One-side electrode of the chip component 20 is electrically continuous with the wiring conductor 14 which is formed on the first surface layer 12, and one-side electrodes of the chip component 21 and the chip component 22 are both electrically connected to the wiring conductor 15 which is formed on the first surface layer 12.

In the circuit board of the present disclosure, the first electrode and the third electrode can be jointed to each other with solder. Each electrode of the three chip components may be connected with solder (not shown). In the circuit board of the present disclosure, the fifth electrode can be jointed to at least one of the first electrode and the third electrode with solder, and the sixth electrode can be connected to the printed wiring board.

In the circuit board of the present disclosure, the fifth electrode and the sixth electrode of the third chip component may be disposed so as to be aligned in a direction which is orthogonal to the first main surface, and a difference between a distance from the fifth electrode to the first main surface and a distance from the sixth electrode to the first main surface is less than half of a distance from the fifth electrode to the sixth electrode.

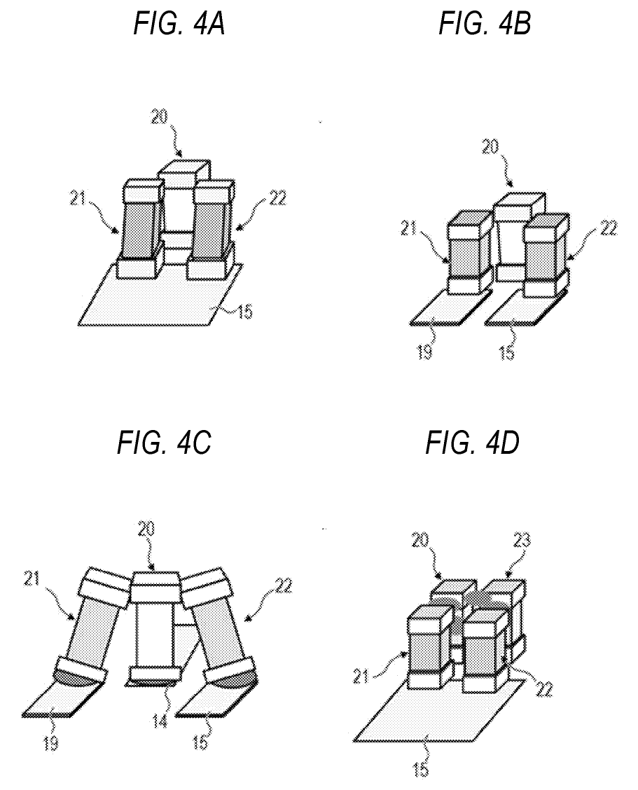

FIGS. 4A-4D are views of the first main surface 11 in FIG. 3 as seen in a direction which extends from the wiring conductor 15 which is formed on the first surface layer 12 to the wiring conductor 14. FIG. 4A corresponds to a mounting structure which is shown in FIG. 3. The chip component 21 and the chip component 22 are both disposed in upright so as to be inclined toward the chip component 20. The chip component 20 is disposed in upright so as to be inclined toward the chip component 21 and the chip component 22. One-side electrodes (second electrode, fourth electrode, and sixth electrode) of the three chip components (chip component 20, chip component 21, and chip component 22) are electrically connected to the first surface layer 12 of the printed wiring board 10, and another-side electrodes (first electrode, third electrode, and fifth electrode) of the chip components are all electrically continuous with each other.

FIGS. 4B-4D are diagrams which show different forms of a connection structure of the first embodiment. In FIG. 4B, the chip component 21 and the chip component 22 are all disposed in upright on the first surface layer 12 of the printed wiring board 10. On the first surface layer 12, one-side electrode (second electrode) of the chip component 21 is electrically connected to a wiring conductor 19, and one-side electrode (fourth electrode) of the chip component 22 is electrically connected to the wiring conductor 15.

The chip component 21 and the chip component 22 may be connected to same wiring conductor as shown in FIG. 4A, or may be connected to different wiring conductors as shown in FIG. 4B. The chip component 20 is disposed in upright on the first surface layer 12 so as to be inclined toward the chip component 21 and the chip component 22. Furthermore, the electrodes of the chip component 20, the chip component 21, and the chip component 22 are electrically continuous with each other.

In FIG. 4C, the chip component 21 and the chip component 22 are mounted upright so as to be inclined and sandwich the chip component 20 from both sides. The electrodes of the three chip components (chip component 20, chip component 21, and chip component 22) which are electrically connected to the first surface layer 12 are connected via a member capable of electrical connection such as solder. In FIG. 4D, four chip components (chip component 20, chip component 21, chip component 22, and chip component 23) are all disposed in upright with respect to the first surface layer 12 of the printed wiring board 10.

One-side electrodes of the four chip components are all electrically connected to the first surface layer 12 of the printed wiring board 10. Another-side electrodes are all electrically continuous with each other via a member capable of electrical connection such as solder. Thus, an angle of the chip components which are relative to the first surface layer 12 of the printed wiring board 10, a method for causing the electrodes to be electrically continuous with each other, etc. can be selected by taking mountability into consideration. A mounting method for the chip components may be selected according to a wiring region in which a filter circuit which includes a plurality of chip components can be mounted.

In the circuit board of the present disclosure, the first chip component can be a resistor component, the second chip component can be a resistor component, and the third chip component can be a reactor component. The reactor component may be a capacitor component or an inductor component. Here, in the first embodiment which is shown in FIG. 3, characteristics of the filter circuit are evaluated in a case that the chip component 20 is a capacitor such as a multilayer ceramic capacitor, and the chip component 21 and the chip component 22 are both chip resistors.

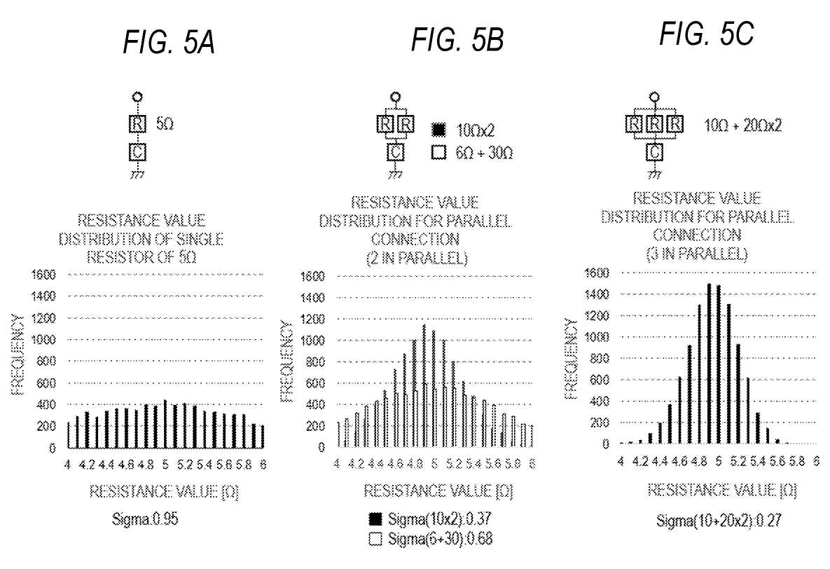

FIGS. 5A-5C illustrate results of comparing variation in resistance values in a case that resistor components and capacitor components are connected in series. FIG. 5A is a diagram which shows a circuit which includes one resistor component and one capacitor component, and a distribution of the variation in the resistance value. Here, a resistor component of 5Ω is selected. Assuming that the variation in the resistance value is ±10%, a result estimated by generating random numbers for 10,000 resistance values is shown in the bar graph in the lower portion of the figures.

FIG. 5B shows a configuration which corresponds to the circuit which is shown in FIG. 3, an example of the circuit which includes two resistors of 10Ω which are connected in parallel, and an another example of the circuit which is formed by combining a resistor of 6Ω and a resistor of 30Ω in parallel. Because the resistor components are connected in parallel, an equivalent resistance value which combines the two types of resistor components is 5Ω, and same filter circuit as in FIG. 5A can be formed.

Assuming that the variation in the resistance value is ±10%, a result which is estimated by generating random numbers for 10,000 resistance values is shown in the lower portion of FIG. 5B, which is a similar case to that in FIG. 5A. The black bar graph represents a distribution of the resistance value which combines two resistors of 10Ω, and the variation in the resistance value which is suppressed more than that for a case in FIG. 5A can be confirmed. The equivalent resistance value which combines 6Ω and 30Ω which are indicated by the white bar graph can also achieve an equivalent resistance value which is closer to the central value of 5Ω as shown in FIG. 5B.

Calculating a specific variation value with a configuration which is shown in FIG. 5B results in 0.37 with the two resistors of 10Ω and in 0.68 with the combination of the resistor of 6Ω and the resistor of 30Ω, while the configuration of FIG. 5A results in 0.95, thus the variation can be confirmed to be suppressed more than that in FIG. 5A. Thus, by combining two resistor components, the variation in the resistance value can be suppressed, variation in filter characteristics can be suppressed, and precision can be enhanced.

FIG. 5C shows a configuration in which three resistor components are combined in order to realize an equivalent resistance value of 5Ω, which includes one resistor component of 10Ω and two resistors components of 20Ω which are connected in parallel. This configuration corresponds to a configuration of FIG. 4D in which three components are used as resistors.

The equivalent resistance of the circuit is 5Ω and is distributed around the central value. A variation range can be confirmed to be further suppressed and to be improved to 0.27 with respect to the configuration in which two resistor components are connected in parallel. Thus, the variation range of the resistance value can be suppressed and high-precision filter characteristics can be obtained by connecting more resistor components in parallel.

In a case that a plurality of resistance components are connected in parallel, component availability can be increased because a selectable range of resistor components is higher than a case that a circuit includes one resistance component. Because components with a greater resistance value can be employed than a case that the circuit includes a single component, effects which disperse heat which are applied to the resistor components and effects which extend service life of the resistor components which are mounted on the printed wiring board can be also obtained.

These effects allow the filter circuit to be applied to a circuit with high power consumption and increase long-term reliability of the mounted components. Moreover, variation in the filter characteristics can be suppressed and component availability can be increased.

FIG. 11 is a perspective view of a printed wiring board 110 of a comparative example. Three chip components (chip component 120, chip component 121, and chip component 122) are disposed on a first main surface 111 of the printed wiring board 110. Each electrode of the three chip components (chip component 120, chip component 121, and chip component 122) is electrically connected to one of a wiring conductor 114, a wiring conductor 115, and a wiring conductor 117 which are formed on a first surface layer 112 of the printed wiring board 110. A second surface layer 113 is disposed at a second main surface 116 of the printed wiring board 110.

In the printed wiring board 110 which is shown in the comparative example, a region corresponding to a projection area of the chip components is required to form a filter circuit. For example, an area of 1.8 mm² is required to mount chip components with a dimension of 0.6 mm in a longitudinal direction and 0.3 mm in a lateral direction. In a case of mounting three chip components, it is necessary to form the wiring conductor 114, the wiring conductor 115, and the wiring conductor 117 to electrically connect the electrodes of the chip components to each other, in addition to an area which is occupied by 5.4 mm² of chip components.

On the other hand, by adopting the mounting structure according to the first embodiment, the two chip components (chip component 21 and chip component 22) can be disposed within the projection area of one chip component. Furthermore, the wiring conductor, which corresponds to the wiring conductor 117 in the comparative example, for connecting the electrodes of the three chip components to each other can be omitted.

By mounting all of the chip component 20, the chip component 21, and the chip component 22 in upright, a circuit can be formed in which four chip components, which includes one capacitor component and three resistor components which are connected in parallel within a region for mounting two chip components on the printed wiring board which is shown in the comparative example, which enables to increase area efficiency by 1.5 times or more.

The chip component 20 is a capacitor, and the chip component 21 and the chip component 22 are resistors, but are not limited thereto. For example, capacity can be increased, and a capacitance value can be adjusted, by using the chip component 20 as a ferrite bead, and the chip component 21 and the chip component 22 as capacitor components. Same effect can be obtained by using a chip-shaped component such as an inductor, a capacitor, a resistor, or a diode. Here, the inductor includes a ferrite bead.

The circuit board (filter circuit) which is shown in FIG. 3 can enhance noise reduction by being implemented near the semiconductor 9, the conversion chip 4, , the connector 5, the connector 6, or the connector 7, which are disposed on the control module 3. In particular, the risk of the electronic equipment malfunctioning can be reduced by implementing the circuit board near the semiconductor 9 in which a pitch of the terminals for mounting on the printed wiring board 10 is narrow.

In this case, the semiconductor 9 is mounted on the first surface layer 12 which is the first main surface 11 of the printed wiring board 10, or on a second surface layer 13 which is a second main surface 16 of the printed wiring board 10. In particular, if terminals which are placed on the semiconductor 9 include a ball grid array (BGA) structure in which the terminals are formed in a matrix, the semiconductor 9 can be disposed on the second surface layer 13 which is located on a surface which is opposite to the chip component 20, the chip component 21, and the chip component 22 of the printed wiring board 10, in order to be used for a circuit which is placed in the center portion of the semiconductor package.

In this case, electrical connection to the terminals of the semiconductor 9 may be made via a via 17 which is formed in the wiring conductor 14 which is connected to the chip component 20 and a via 18 which is formed in the wiring conductor 15 which is connected to the chip component 21 and the chip component 22.

In a typical mounting structure which is shown in the comparative example, the electrodes of the plurality of chip components are all electrically connected to the printed wiring board 10, which induces implementing noise countermeasures. The area, which is occupied by the circuit board (filter circuit) which includes the plurality of chip components, is large, and a via needs to be formed in the wiring conductor 117 which is shown in the comparative example for electrical connection to the three chip components. Even for a circuit in which application is difficult due to a large area which is occupied by chip components and wiring conductors, the circuit board (filter circuit) which is shown in the first embodiment can be applied, and noise can be reduced.

Methods of mounting the plurality of chip components in upright on the first surface layer 12 of the printed wiring board 10 include a method of reflow mounting by using a mounting machine, and a method of creating a filter component unit which includes the plurality of chip components in advance and subsequently mounting the filter component unit on the first surface layer 12 of the printed wiring board 10. In this case, the member for allowing the electrodes of the chip components to be electrically continuous with each other does not need to be limited to solder, and a method which is capable of electrical connection such as an adhesive can be selected. The adhesive may contain a resin to provide adhesion and contain a conductor to provide electrical conduction.

A configuration in which the plurality of chip components are mounted on the printed wiring board 10 is shown, but the plurality of chip components may also be mounted on housing wiring which is formed on a metal housing which is connected to the control module 3. This configuration can be widely applied to electrical signal or power supply paths.

The printed wiring board 10 does not need to be limited to a two-layer structure which includes the first surface layer 12 and the second surface layer 13, but can also be implemented as a single-sided board which includes only the first surface layer 12, or as a printed wiring board with two or more layers with an inner layer conductor (not shown) between the first surface layer 12 and the second surface layer 13.

In the circuit board of the present disclosure, the first electrode and the second electrode of the first chip component can be disposed so as to be aligned in a direction which is orthogonal to the first main surface, and the third electrode and the fourth electrode of the second chip component can be disposed so as to be aligned in the direction which is orthogonal to the first main surface. In the present disclosure, the term "upright" just means that two electrodes of a chip component are disposed so as to be aligned in a direction which is orthogonal to a main surface. In this case, part of each of the two electrodes may exist on a normal to the main surface. An axis passes through the two electrodes of the chip component, around which the chip component is rotationally symmetric, is referred as a principal axis of the chip component. An angle, which is formed by the principal axis of the upright chip component and the main surface of a circuit board, typically exceeds 45 degrees. A typical example of "upright" is "vertically standing". The angle which is formed by the principal axis of the vertically standing chip component and the main surface of the circuit board is typically 90 degrees, but may be 60 degrees or more, and is not necessarily limited to being perpendicular.

### Second Embodiment

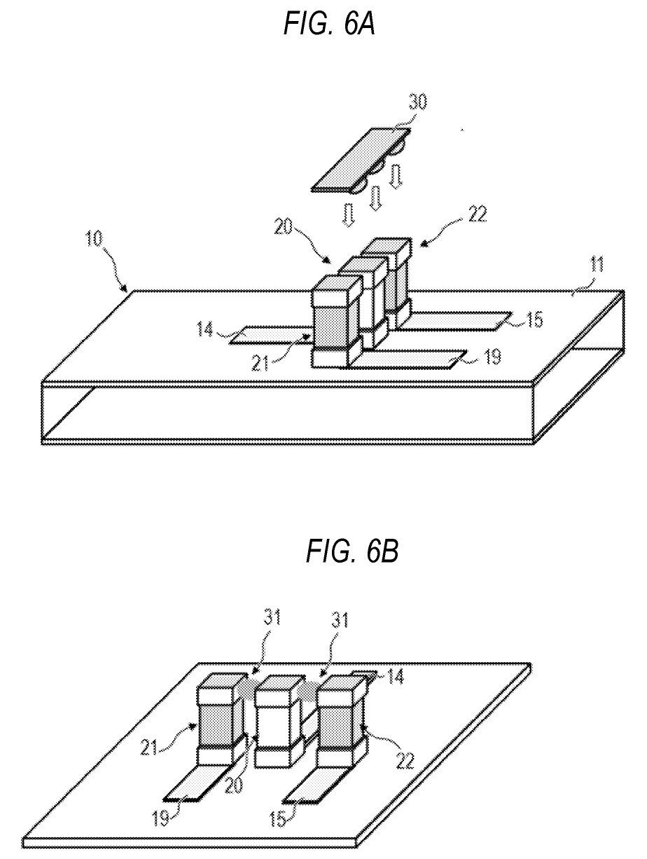

Details of a second embodiment will be described by using FIGS. 6A and 6B. FIG. 6A is a perspective view of a first main surface 11 of a printed wiring board 10. Three chip components (chip component 20, chip component 21, and chip component 22) are disposed on a first surface layer 12, which is the first main surface 11, which is a similar case to that in the first embodiment.

Only one-side electrodes (second electrode, fourth electrode, and sixth electrode) of all the three chip components are electrically connected to the first surface layer 12 of the printed wiring board 10, and the three chip components are all mounted in upright. Another-side electrodes (first electrode, third electrode, and fifth electrode) of the chip component 20, the chip component 21, and the chip component 22 are electrically connected by a conductive member 30.

FIG. 6B is a diagram which shows a mounting structure of a variation of the second embodiment. The three chip components (chip component 20, chip component 21, and chip component 22) are all mounted in upright on the first surface layer 12 of the printed wiring board 10, and another-side electrodes (first electrode, third electrode, and fifth electrode) are each electrically connected by a conductive member 31, which is a similar case to that in FIG. 6A.

By adopting such a connection structure, a distance at which the plurality of chip components are disposed, as well as component size can be freely selected.

### Third Embodiment

A circuit board of the present disclosure includes: a printed wiring board; and a first chip component, a second chip component, and a third chip component which are placed on a first main surface of the printed wiring board. The first chip component is a resistor component which includes a first electrode and a second electrode. The second chip component is a resistor component which includes a third electrode and a fourth electrode. The third chip component is a reactor component which includes a fifth electrode and a sixth electrode. The first electrode, the third electrode, and the fifth electrode are connected to each other, and the second electrode and the fourth electrode are connected to each other. The third chip component is disposed between the second chip component and the first main surface.

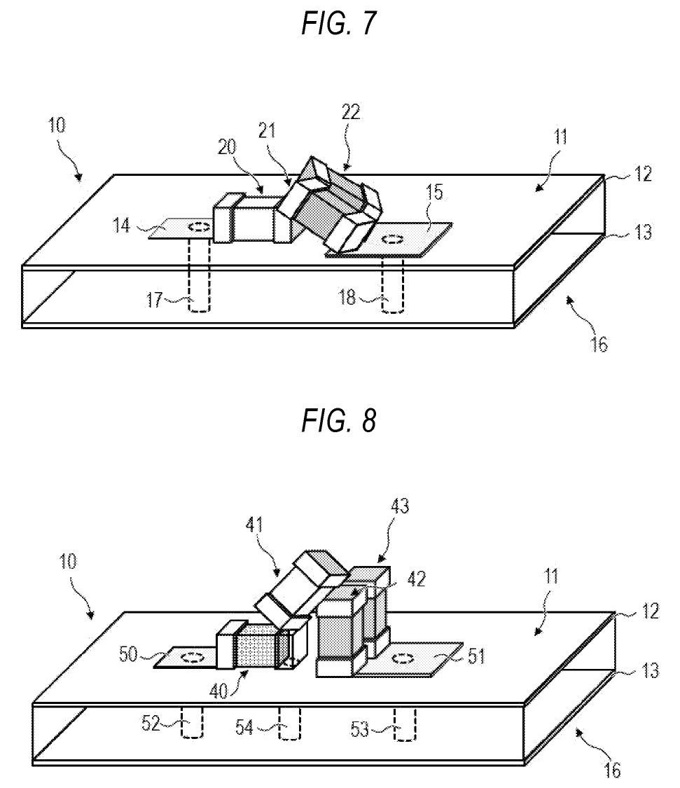

Details of a third embodiment will be described by using FIG. 7. Similar to the first embodiment, three chip components (chip component 20, chip component 21, and chip component 22) are disposed on a first main surface 11 of a printed wiring board 10. Two electrodes of the chip component 20 are both electrically connected to a first surface layer 12 of the printed wiring board 10, which is a similar case to that in the first embodiment.

Only one-side electrodes (fourth electrode and sixth electrode) of the chip component 21 and the chip component 22 are electrically connected to the first surface layer 12 of the printed wiring board 10, and another-side electrodes (third electrode and fifth electrode) are electrically continuous with each other.

The electrodes at which the chip component 21 and the chip component 22 are electrically continuous with each other are both electrically continuous with the electrode of the chip component 20 on a side which is not connected to a wiring conductor 14 without passing through the first surface layer 12 of the printed wiring board 10.

In the circuit board of the present disclosure, the reactor component may be a capacitor component or an inductor component.

In the circuit board of the present disclosure, the first electrode and the third electrode can be jointed to each other with solder. The circuit board of the present disclosure can include a conductor member (wiring conductor 14 and wiring conductor 15) which is placed on the first main surface 11 of the printed wiring board 10, wherein the second electrode can be jointed to the conductor member with solder, and the fourth electrode can be jointed to the conductor member with solder. “Being jointed to each other with solder”, may be rephrased as being soldered to each other. “Joining each other with solder” may be rephrased as soldering each other.

In the circuit board of the present disclosure, the fifth electrode can be jointed to at least one of the first electrode and the third electrode with solder, and the sixth electrode can be connected to the printed wiring board 10.

If the chip component 20 is a capacitor and the chip component 21 and the chip component 22 are resistors, a circuit board (filter circuit) which is shown at upper part of FIG. 5B can be formed.

By adopting such a configuration, a region for disposing each electrode of the chip component 21 and the chip component 22, which are electrically continuous with the chip component 20 on the first surface layer 12 of the printed wiring board 10, can be reduced. Furthermore, the wiring conductor, which corresponds to the wiring conductor 117 which is shown in the comparative example, that connects the three chip components can be reduced, which induces that an area which is occupied by the chip components can be reduced in size.

In a case of implementing a filter circuit in a condition in which a semiconductor 9, etc. in a control module 3 is disposed on a second surface layer 13 which is opposite to the first surface layer 12 of the printed wiring board 10, a via 17 and a via 18 are formed in the wiring conductor 14 and the wiring conductor 15, which facilitates connection.

In the present embodiment, the region for disposing each one-side electrode of the chip component 21 and the chip component 22 can be reduced, and the filter circuit can be implemented. Thus, in the present embodiment, both miniaturization of the printed wiring board 10 and noise reduction can be achieved.

### Fourth Embodiment

In addition to the configuration of the first embodiment, the circuit board of the present disclosure can include a fourth chip component which is placed on the first main surface of the printed wiring board. The fourth chip component can include a seventh electrode and an eighth electrode. The sixth electrode and the eighth electrode can be connected to each other. The eighth electrode can be located between the sixth electrode and the first main surface.

Details of a fourth embodiment will be described using FIG. 8. FIG. 8 is a perspective view of a printed wiring board 10 which constitutes a control module according to the fourth embodiment. At least four chip components are disposed on a first main surface 11 of the printed wiring board 10.

The electrodes of the fourth chip component (chip component 40) are all electrically connected to a first surface layer 12 of the printed wiring board 10. A first chip component (chip component 42) and a second chip component (chip component 43) are disposed in upright on the printed wiring board 10. One-side electrodes of the chip component 42 and the chip component 43 are electrically connected to a wiring conductor 51 which is formed on the first surface layer 12.

Another-side electrodes (first electrode and third electrode) of the chip component 42 and the chip component 43 are electrically continuous with each other, and are also electrically continuous with one-side electrode (fifth electrode) of a third chip component (chip component 41). Another-side electrode (sixth electrode) of the chip component 41 is electrically continuous with one-side electrode of the chip component 40.

Here, an effect will be described about reducing the area, which is occupied by the chip components, in size in a case that the chip component 40, the chip component 41, the chip component 42, and the chip component 43 are all components which are same in size. The chip component 42 and the chip component 43 can both be disposed in a region necessary for disposing one chip component on the first surface layer 12 of the printed wiring board 10. Furthermore, the electrodes of the chip component 41 are directly electrically continuous with the electrodes of all other chip components, and the area which is occupied on the first surface layer 12 of the printed wiring board 10 can be substantially reduced.

Therefore, the four chip components can all be accommodated within a region in which two chip components are projected, and area efficiency can be doubled. The effect of reducing the area which is occupied by the chip components in size can be enhanced by disposing the chip components, which are connected in parallel, in upright on the printed wiring board.

The chip component 42 and the chip component 43 are disposed in upright on the first main surface 11 of the printed wiring board 10, the area which is occupied by the chip components on the first surface layer 12 can be reduced by using a configuration in which the chip component 41 is disposed in upright, the one-side electrode (fifth electrode) of the chip component 41 is electrically connected to the wiring conductor 51, and one-side electrodes (first electrode and third electrode) of the chip components 42 and 43 are electrically continuous with another-side electrode (sixth electrode) of the chip component 41.

Another-side electrodes (second electrode and fourth electrode) of the chip components 42 and 43 are electrically continuous with one-side electrode of the chip component 40. Thus, an order of electrically connecting the three types of chip components can be changed according to a procedure of mounting the chip components.

The chip component 41 can be directly electrically continuous with the chip component 40 and one-side electrode of each of the chip component 42 and the chip component 43, but may also be connected via a conductive member which is capable of electrical connection such as solder. In order to reliably mount the chip component 41, an auxiliary member can be used for positioning purposes. An effective equivalent resistance value when the electrodes are electrically continuous can be low.

In the circuit board of the present disclosure, the first chip component can be a resistor component, the second chip component can be a resistor component, the third chip component can be a reactor component, and the fourth chip component can be a reactor component.

In the circuit board of the present disclosure, the printed wiring board can include a second main surface on a side which is opposite to the first main surface. A semiconductor element can be mounted on the second main surface. The printed wiring board can have a first terminal through which a power supply potential is supplied to the semiconductor element and a second terminal through which a ground potential is supplied to the semiconductor element. The second electrode and the fourth electrode can each be connected to one side of the first terminal and the second terminal, and the sixth electrode can be connected to another side of the first terminal and the second terminal.

Here, by using the chip component 40 as a ferrite bead, the chip component 41 as a capacitor, and the chip component 42 and the chip component 43 as resistors, the circuit board (filter circuit) can be formed. For example, the filter circuit can be formed between a wiring for supplying the power supply potential to a semiconductor and a wiring for supplying the ground potential.

A pitch of the terminals which connects a semiconductor component to the printed wiring board becomes narrow. As a power supply voltage which is supplied for circuit operation decreases, the number of countermeasure components for reducing noise which is generated during operation of the semiconductor and the scale of the circuit which requires such countermeasures tend to increase. A method of densely mounting chip components near the semiconductor device without processing the chip components is effective.

In this case, parasitic resistance and parasitic inductance of the wiring conductors which are connected to electrodes of the semiconductor can be suppressed. The semiconductor is disposed on the second surface layer 13, which is a second main surface 16 which is opposite to the first surface layer 12 of the printed wiring board 10. Connection to the electrodes of the semiconductor is facilitated by preparing a via 53 in the wiring conductor 51 which is formed on the first surface layer 12, a via 52 in a wiring conductor 50, and a via 54 within a region in which the electrodes of the chip component 40 are projected.

By adopting such a configuration, a circuit can be realized in which all the electrodes of the chip component 40 and one-side electrodes of the chip component 42 and the chip component 43 are electrically connected to the electrodes of the semiconductor.

In other words, in a circuit configuration in which a ferrite bead, a capacitor component, and resistor components are connected in series, all components can be electrically connected to the electrodes of the semiconductor from the points at which all the components are interconnected, and an enhanced power supply noise suppression effect can be expected. In particular, high-precision filter characteristics can be obtained because resistor components can be connected in parallel.

Note that a method of forming the via 54 within the region in which the one-side electrode of the chip component 40 is projected has been described, but connection may be made after forming a wiring conductor (not shown). A structure may be selected by taking a manufacturing method, etc. of the printed wiring board into consideration. The wiring conductor 51 is electrically connected to both the chip component 42 and the chip component 43, but separate wiring conductors may be formed.

The four chip components which are same in size have been explained but may be different in component sizes.

A configuration has been described in which three types of chip components are combined, but the configuration is not limited to an inductor component, a capacitor component, and a resistor component, and can also be applied to a chip component such as a diode. A configuration is shown in which two resistor components are connected in parallel, but the configuration is not limited to the resistor components.

An effect of suppressing the variation which are shown in FIGS. 5A-5C can be obtained by connecting the resistor components in parallel. The chip components need not be limited to two terminals, and can also be implemented as chip components with three terminals, four terminals, etc.

### Fifth Embodiment

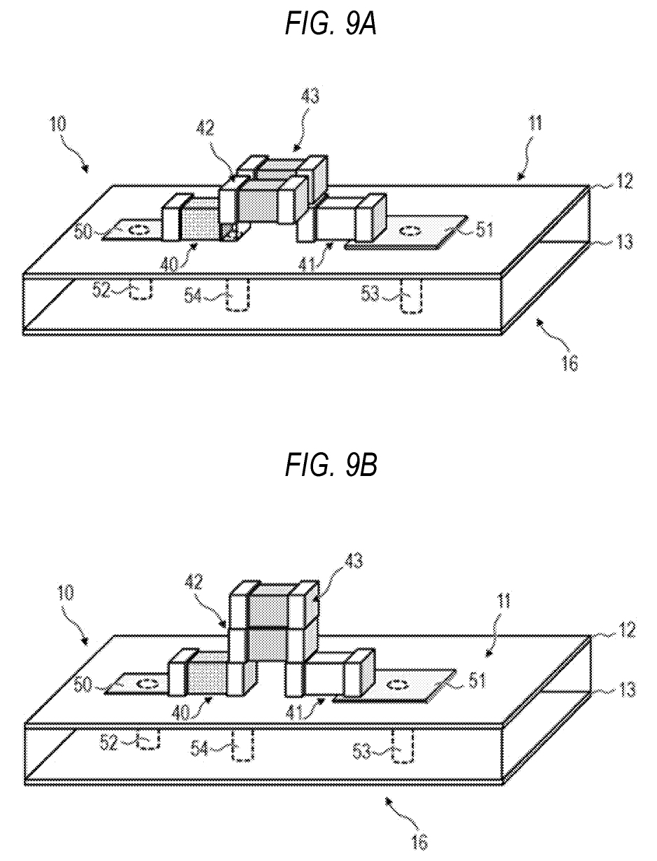

Details of a fifth embodiment will be described using FIGS. 9A and 9B. FIGS. 9A and 9B are perspective views of a printed wiring board 10 which constitutes a control module according to the fifth embodiment. Four chip components are disposed on a first main surface 11 of the printed wiring board 10, which is a similar case to that in the fourth embodiment which is shown in FIG. 8.

A circuit board of the present disclosure includes: a printed wiring board; and a first chip component, a second chip component, and a third chip component which is placed on a first main surface of the printed wiring board. The first chip component is a resistor component which includes a first electrode and a second electrode. The second chip component is a resistor component which includes a third electrode and a fourth electrode. The third chip component is a reactor component which includes a fifth electrode and a sixth electrode. The first electrode, the third electrode, and the fifth electrode are connected to each other, and the second electrode and the fourth electrode are connected to each other. The third chip component is disposed between the second chip component and the first main surface.

The circuit board in the present disclosure can include a fourth chip component which is placed on the first main surface of the printed wiring board, wherein the fourth chip component can be disposed between the second chip component and the first main surface. In FIG. 9A, the third chip component and the fourth chip component (chip component 40 and chip component 41) are disposed on a first surface layer 12, which is the first main surface 11 of the printed wiring board 10. One-side electrodes of the chip component 40 and the chip component 41 are respectively electrically connected to a wiring conductor 50 and a wiring conductor 51 which are formed on the first surface layer 12.

The first chip component (chip component 42) and the second chip component (chip component 43) are mounted on another-side electrodes of the two chip components, and are electrically continuous.

In the circuit board of the present disclosure, the reactor component may be a capacitor component or an inductor component.

In the circuit board of the present disclosure, the first electrode and the third electrode can be jointed to each other with solder. The circuit board of the present disclosure can include a conductor member (wiring conductor 50 and wiring conductor 51) which is placed on the first main surface 11 of the printed wiring board 10, wherein the second electrode can be jointed to the conductor member with solder, and the fourth electrode can be jointed to the conductor member with solder.

In the circuit board of the present disclosure, the fifth electrode can be jointed to at least one of the first electrode and the third electrode with solder, and the sixth electrode can be connected to the printed wiring board 10.

In the fourth embodiment, miniaturization is achieved by disposing two chip components in upright on the first main surface 11 of the printed wiring board 10, whereas in the fifth embodiment, four chip components are disposed by bridging the chip component 40 and the chip component 41 when the first main surface 11 is viewed from above.

By adopting such a configuration, a via 52, a via 53, and a via 54 can be formed in a circuit configuration in which three types of chip components are connected in series in order to connects all components to each other, which is a similar case to that in the fourth embodiment. Therefore, in case that a semiconductor (not illustrated) is displaced on a second main surface 16 of the printed wiring board 10, electrical connection to electrodes of the semiconductor can be made.

A circuit board of the present disclosure includes: a printed wiring board; and a first chip component, a second chip component, and a third chip component which are placed on a first main surface of the printed wiring board. The first chip component is a resistor component which includes a first electrode and a second electrode. The second chip component is a resistor component which includes a third electrode and a fourth electrode. The third chip component is a reactor component which includes a fifth electrode and a sixth electrode. The first electrode, the third electrode, and the fifth electrode are connected to each other, and the second electrode and the fourth electrode are connected to each other. The first chip component is disposed between the second chip component and the first main surface.

The circuit board of the present disclosure can include a fourth chip component which is placed on the first main surface of the printed wiring board, wherein the fourth chip component can be disposed between the second chip component and the first main surface. FIG. 9B is a diagram which shows a variation of the fifth embodiment. A difference from FIG. 9A is that a chip component 43 is disposed on top of a chip component 42.

In a case that the chip component 42 and the chip component 43 are used as resistors, an equivalent resistance value can be slightly adjusted in addition to obtaining same effect of reducing an area which is occupied by the chip components as that in FIG. 9A.

The equivalent resistance value in the embodiment which is shown in FIG. 9A is of 5Ω if the chip component 42 and the chip component 43 are resistor components of 10Ω, whereas the equivalent resistance in the embodiment which is shown in FIG. 9B changes beyond 5Ω because a parasitic resistance value of a path connecting to the chip component 42 and the chip component 43 differs. The resistance value can be adjusted by interposing a conductive member on the path which connects the chip component 42 and the chip component 43. Filter characteristics can be controlled by adopting the fifth embodiment.

### Sixth Embodiment

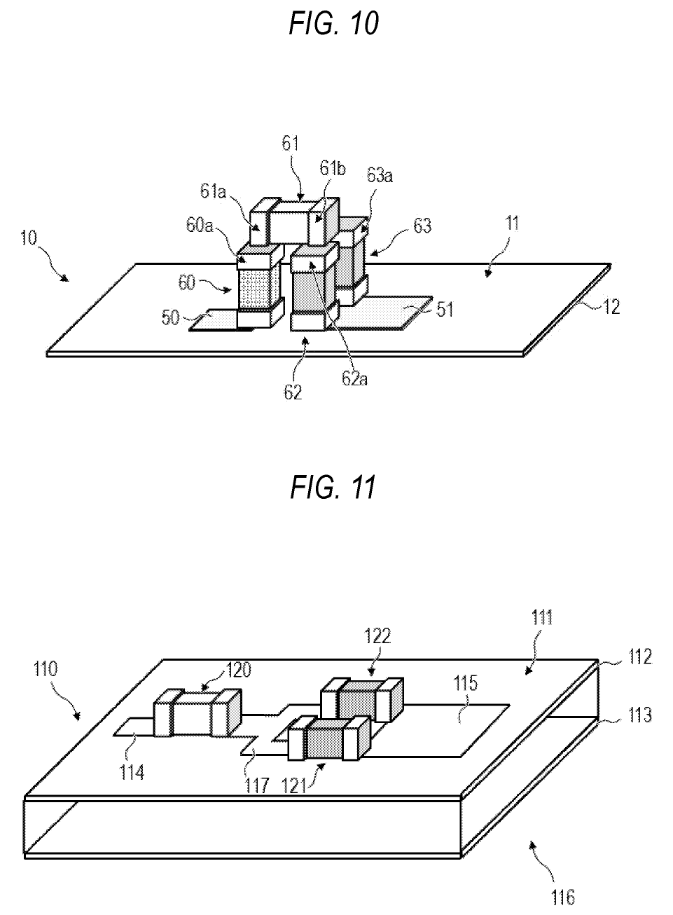

Details of a sixth embodiment will be described by using FIG. 10. FIG. 10 is a perspective view of a printed wiring board 10 which constitutes a control module according to the sixth embodiment. Only a first main surface 11 of the printed wiring board 10 is shown. Four chip components of three different types are disposed on a first surface layer 12 of the first main surface 11, which is a similar case to that in the fourth and fifth embodiments.

A chip component 60, a chip component 62, and a chip component 63 are all disposed in upright on the first surface layer 12 of the printed wiring board 10. Only one-side electrode of all the three chip components are electrically connected to the first surface layer 12. The chip component 60 is electrically connected to a wiring conductor 50, and the chip component 62 and the chip component 63 are both electrically connected to a wiring conductor 51.

In this case, in the three chip components, electrodes which are located away from the first surface layer 12 are respectively referred to as a terminal 60a, a terminal 62a, and a terminal 63a. Then one-side electrode 61a of a chip component 61 is electrically continuous with the terminal 60a, and another-side electrode 61b of the chip component 61 is electrically continuous with both the terminal 62a and the terminal 63a.

By adopting such a configuration, the four chip components can be disposed in an area which is occupied by the chip components which is reduced in size. For example, a π-type filter can be formed by using the chip component 60, the chip component 62, and the chip component 63 as capacitors, and the chip component 61 as an inductor.

A configuration for allowing the chip components to be electrically continuous need not be limited to a configuration in which the electrodes are directly connected to each other, and connection may be made via a conductive member which is capable of electrical connection such as solder. The chip components do not all need to be same in size.

According to the present disclosure, the area which is occupied by the circuit which includes the chip components can be reduced in size.

The present disclosure is not limited to the above-described embodiments and can be modified in various ways. For example, an embodiment in which part of one embodiment is added to another embodiment, or in which part of one embodiment is replaced with part of another embodiment also falls within the scope of the present disclosure.

Note that the above-described embodiments are merely examples for implementing the present disclosure, and these should not be interpreted as limiting the technical scope of the present disclosure. That is, the present disclosure can be implemented in various forms without departing from its technical idea or its main features.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-038181, filed Mar. 11, 2025, which is hereby incorporated by reference herein in its entirety.

What is claimed is:

1. A circuit board comprising:
a printed wiring board; and
a first chip component, a second chip component, and a third chip component which are placed on a first main surface of the printed wiring board, wherein
the first chip component has a first electrode and a second electrode,
the second chip component has a third electrode and a fourth electrode,
the third chip component has a fifth electrode and a sixth electrode,
the first electrode, the third electrode, and the fifth electrode are connected to each other, and the second electrode and the fourth electrode are connected to the printed wiring board,
a distance between the first electrode and the first main surface is greater than a distance between the second electrode and the first main surface, and
a distance between the third electrode and the first main surface is greater than a distance between the fourth electrode and the first main surface.

2. A circuit board comprising:
a printed wiring board; and
a first chip component, a second chip component, and a third chip component which are placed on a first main surface of the printed wiring board, wherein
the first chip component is a resistor component which includes a first electrode and a second electrode,
the second chip component is a resistor component which includes a third electrode and a fourth electrode,
the third chip component is a reactor component which includes a fifth electrode and a sixth electrode,
the first electrode, the third electrode, and the fifth electrode are connected to each other, and the second electrode and the fourth electrode are connected to each other, and
the first chip component or the third chip component is disposed between the second chip component and the first main surface.

3. The circuit board according to claim 2, wherein
the first electrode and the third electrode are jointed to each other with solder, and/or
the fifth electrode is jointed to at least one of the first electrode and the third electrode with solder.

4. The circuit board according to claim 1, wherein
the first chip component is a resistor component,
the second chip component is a resistor component, and
the third chip component is a reactor component.

5. The circuit board according to claim 2, wherein
the reactor component is a capacitor component.

6. The circuit board according to claim 2, wherein
the reactor component is an inductor component.

7. The circuit board according to claim 1, wherein
the first electrode and the third electrode are jointed to each other with solder.

8. The circuit board according to claim 1, further comprising a conductor member which is placed on the first main surface of the printed wiring board, wherein
the second electrode is jointed to the conductor member with solder, and the fourth electrode is jointed to the conductor member with solder.

9. The circuit board according to claim 1, wherein
the fifth electrode is jointed to at least one of the first electrode and the third electrode with solder.

10. The circuit board according to claim 1, wherein
the sixth electrode is connected to the printed wiring board.

11. The circuit board according to claim 1, wherein
the first electrode, the third electrode, and the fifth electrode are connected to each other.

12. The circuit board according to claim 1, wherein
the first electrode and the second electrode of the first chip component are disposed so as to be aligned in a direction which is orthogonal to the first main surface, and the third electrode and the fourth electrode of the second chip component are disposed so as to be aligned in the direction which is orthogonal to the first main surface.

13. The circuit board according to claim 1, wherein
a distance between the fifth electrode and the first main surface is greater than a distance between the sixth electrode and the first main surface.

14. The circuit board according to claim 1, wherein
the fifth electrode and the sixth electrode of the third chip component are disposed so as to be aligned in a direction which is orthogonal to the first main surface.

15. The circuit board according to claim 1, wherein
a difference between a distance from the fifth electrode to the first main surface and a distance from the sixth electrode to the first main surface is less than half of a distance from the fifth electrode to the sixth electrode.

16. The circuit board according to claim 1, further comprising a fourth chip component which is placed on the first main surface of the printed wiring board, wherein
the fourth chip component has a seventh electrode and an eighth electrode,
the sixth electrode and the eighth electrode are connected to each other, and
the eighth electrode is located between the sixth electrode and the first main surface.

17. The circuit board according to claim 2, further comprising a fourth chip component which is placed on the first main surface of the printed wiring board, wherein
the fourth chip component is disposed between the second chip component and the first main surface.

18. The circuit board according to claim 16, wherein
the fourth chip component is a reactor component.

19. The circuit board according to claim 1, wherein
the printed wiring board includes a second main surface on a side which is opposite to the first main surface,
a semiconductor element is disposed on the second main surface,
the printed wiring board has a first terminal through which a power supply potential is supplied to the semiconductor element and a second terminal through which a ground potential is supplied to the semiconductor element, and
the second electrode and the fourth electrode are each connected to one side of the first terminal and the second terminal, and the sixth electrode is connected to another side of the first terminal and the second terminal.

20. Electronic equipment comprising:
the circuit board according to claim 1, an electrical apparatus, and a wiring component which is configured to connect the electrical apparatus and the circuit board.

21. Electronic equipment comprising:
the circuit board according to claim 2, an electrical apparatus, and a wiring component which is configured to connect the electrical apparatus and the circuit board.
